(19) United States
(12) Patent Application Publication
(10) Pub. No.: US 2019/0088912 A1
(43) Pub. Date: Mar. 21, 2019

(54) BATTERY CONNECTION MODULE

(71) Applicant: Molex, LLC, Lisle, IL (US)

(72) Inventors: Siow-Pheng GOH, Singapore (SG); Kian Heng LIM, Singapore (SG)

(73) Assignee: Molex, LLC, Lisle, IL (US)

(21) Appl. No.: 16/133,870

(22) Filed: Sep. 18, 2018

(30) Foreign Application Priority Data
Sep. 20, 2017 (CN) 201710861594.9
Aug. 6, 2018 (CN) 201810884832.2

(51) Int. Cl. H01M 2/10; H05K 1/18; H01M 2/22

(52) U.S. Cl. CPC H01M 2/1016; H01M 2010/4271; H01M 2/22; H05K 1/189

(57) ABSTRACT

A battery connection module is adapted to connect a battery pack, the battery connection module comprises: a carrying tray; a plurality of busbars mounted on the carrying tray and adapted to electrically connect a plurality of batteries of the battery pack; a battery management system (BMS) mounted on the carrying tray, positioned above the flexible circuit board and comprising a connector; and a flexible circuit board mounted on the carrying tray, mechanically and electrically connected to the plurality of busbars and comprising a body portion and an extending flexible mating portion, a distal end of the flexible mating portion is connected to the connector of the BMS. The BMS is directly mounted on and coupled to the carrying tray and is electrically connected with the busbars via the flexible circuit board, so that they are integrated to an integrated module that facilitates subsequent assembly and use.

### RELATED APPLICATIONS

This application claims priority to Chinese Application No. 201710861594.9, filed Sep. 20, 2017, and Chinese Application No. 201810884832.2, filed Aug. 6, 2018, both of which are incorporated herein by reference in their entirety.

### TECHNICAL FIELD

The present disclosure relates to a battery connection module, and particularly to a battery connection module which is used to connect rechargeable batteries in series for high power output.

### BACKGROUND ART

A battery system, in which a plurality of electrochemical rechargeable batteries, such as batteries for a vehicle, are arranged side by side to form a battery pack generally, generally connects the batteries in series by a battery connection module to form a pair of output electrodes, and the battery connection module is also provided with a control circuit to connect a Battery Management System (abbreviated as BMS).

A battery module is disclosed in the Chinese patent application publication No. CN102751465B (corresponding to JP2012-226969A), which is connected to a mating-side electrical connector of an external electrical processing device via an electrical connector at a distal end of a flexible flat cable (FFC). The flexible flat cable (FFC) has to extend a long distance to connect to the external electrical processing device (equivalent to a BMS) and need to achieve the connection by these two connectors which are mated with each other.

Chinese patent application publication No. CN105144463A (corresponding to US 2016/0043446, JP2012-226969A and WO2014/173684A2) discloses a battery contact system for an electrochemical device, in which a monitoring unit (equivalent to a BMS) has a pluggable contact connector, a signal transmission system includes one or more signal lines, and the signal line electrically connect each signal source to a signal line connector. The pluggable contact connector of the monitoring unit is mated with the signal line connector of the signal transmission system. Although the monitoring unit is received in a carrying assembly, the signal transmission system is connected to the signal line connector by a plurality of signal lines, and needs to connect with the monitoring unit by the two connectors which are mated with each other.

### SUMMARY

Therefore, one of the objects of the present disclosure is to provide a battery connection module which has a BMS and reduces the number of the connector.

Accordingly, in some embodiments, a battery connection module of the present disclosure is adapted to connect a battery pack, the battery connection module comprises a carrying tray, a plurality of busbars, a battery management system (BMS) and a flexible circuit board. The plurality of busbars are mounted on the carrying tray and adapted to electrically connect a plurality of batteries of the battery pack. The BMS is mounted on the carrying tray, positioned above the flexible circuit board and comprises a connector. The flexible circuit board is mounted on the carrying tray, mechanically and electrically connected to the plurality of busbars and comprises a body portion and an extending flexible mating portion, a distal end of the flexible mating portion is connected to the connector of the BMS.

In some embodiments, the flexible mating portion is formed by cutting the body portion.

In some embodiments, three sides of the flexible mating portion are disconnected with the body portion, so that the flexible mating portion is formed as an elongated shape and makes one end of the flexible mating portion connected with the body portion, and the other end of the flexible mating portion has exposed conductive wires to mate with the connector of the BMS.

In some embodiments, the flexible mating portion extends outwardly from one end edge of the body portion of the flexible circuit board.

In some embodiments, the flexible mating portion bends reversely and then mates with the flexible circuit board connector.

In some embodiments, the connector is a flexible circuit board connector, the flexible mating portion has exposed conductive wires to mate with the flexible circuit board connector.

In some embodiments, the flexible mating portion is mounted to another connector to correspondingly mate with the connector of the BMS.

In some embodiments, the carrying tray has a mounting position where the BMS is provided so as to allow the BMS to be positioned above the flexible circuit board.

In some embodiments, the carrying tray further has a plurality of first mounting structures provided on a circumferential side of the mounting position, and the BMS has a plurality of second mounting structures respectively corresponding to the plurality of first mounting structures to fix the BMS on the mounting position.

In some embodiments, the plurality of first mounting structures are positioning posts and/or locking holes, the plurality of second mounting structures are through holes corresponding to the positioning posts and/or the locking holes.

In some embodiments, the mounting position is defined by four protruding blocks, the positions of the protruding blocks respectively correspond to four corners of the BMS, the plurality of first mounting structures are respectively provided on the protruding blocks.

In some embodiments, the flexible circuit board further comprises a plurality of conductive plates which are connected to the body portion and respectively mechanically and electrically connected to the plurality of busbars.

In some embodiments, the flexible circuit board further comprises a plurality of upper position-limiting plates which are connected to the body portion and respectively protrudes above the plurality of busbars.

In some embodiments, each upper position-limiting plate has a fixing hole, the carrying tray has a plurality of fixing posts respectively passing through the plurality of fixing holes.

In some embodiments, the flexible circuit board has a plurality of mounting holes, the carrying tray has a plurality of mounting posts respectively passing through the plurality of mounting holes.

The present disclosure has the following effects: the BMS is directly mounted on and coupled to the carrying tray and is electrically connected with the busbars via the flexible circuit board, so that they are integrated to an integrated module that facilitates subsequent assembly and use. Moreover, the BMS only needs to be provided with one flexible circuit board connector to directly connect with the flexible circuit board, which can reduce the number of components and save cost.

Furthermore, the flexible mating portion connected to the BMS is formed by cutting the body portion constituting the flexible circuit board, which can effectively utilize the space, and is easy to cooperate to the position where the BMS is coupled to the carrying tray, so that the position where the BMS is provided has flexibility of change.

### BRIEF DESCRIPTION OF THE DRAWINGS

Other features and effects of the present disclosure will be apparent from the embodiments with reference to figures, in which:

FIG. 1 is a perspective view of an embodiment of the battery connection module of the present disclosure and a battery pack;

FIG. 2 is an exploded perspective view of the embodiment and the battery pack;

FIG. 3 is an exploded perspective view of a carrying tray and busbars of the embodiment;

FIG. 4 is a perspective view of the embodiment;

FIG. 5 is an exploded perspective view of the embodiment;

FIG. 6 is an exploded perspective view of the embodiment, in which a BMS is not shown;

FIG. 7 is an exploded perspective view of a flexible circuit board of the embodiment;

FIG. 8 is a perspective view of another embodiment of the battery connection module of the present disclosure; and

FIG. 9 is a perspective view showing details of a flexible mating portion of the other embodiment.

### DETAILED DESCRIPTION OF THE PREFERRED EMBODIMENTS

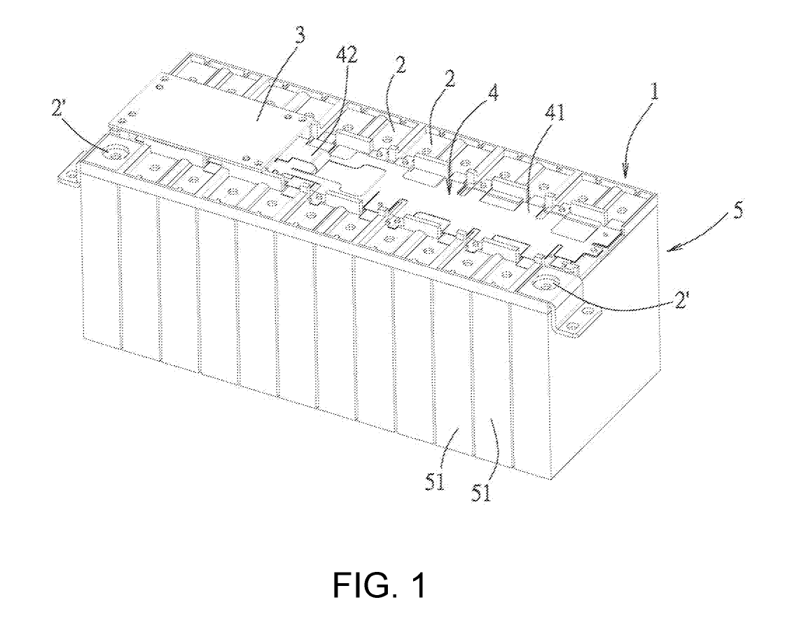

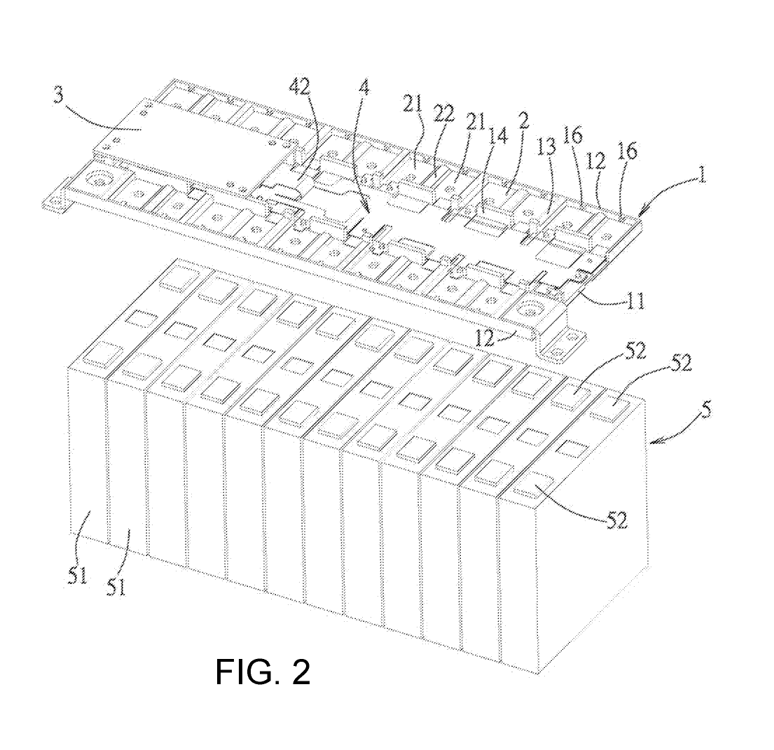

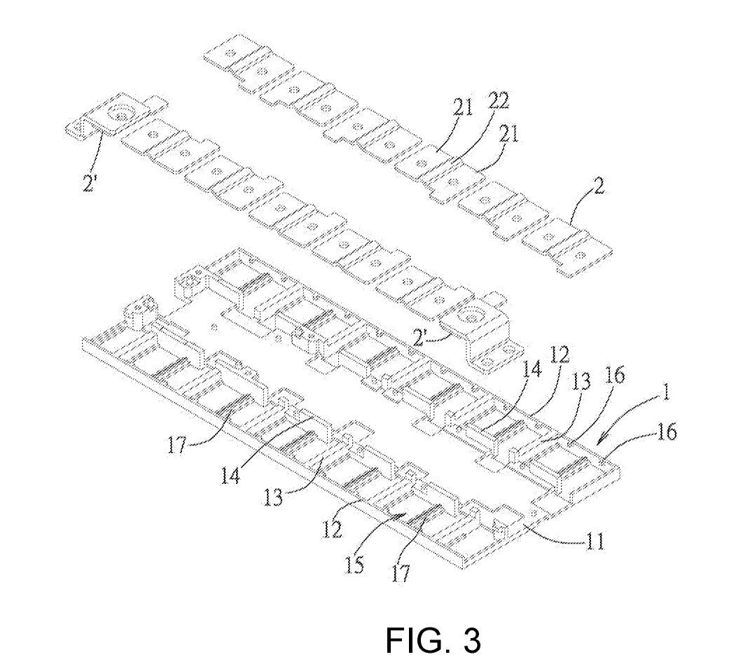

Referring to FIG. 1 to FIG. 3, an embodiment of a battery connection module of the present disclosure is adapted to connect a battery pack 5, the battery connection module comprises a carrying tray 1, a plurality of busbars 2, a Battery Management System 3 (abbreviated as BMS) and a flexible circuit board 4.

The plurality of busbars 2 are mounted on the carrying tray 1, and are adapted to electrical connect a plurality of batteries 51 of the battery pack 5. Specifically, the carrying tray 1 is made of an insulating material, and has a base wall 11, two frame walls 12 facing each other and connected to two sides of the base wall 11, a plurality of spacing walls 13 and a plurality of position-limiting walls 14, the frame walls 12, the spacing walls 13 and the position-limiting walls 14 cooperatively define a plurality of mounting grooves 15 to respectively accommodate the plurality of busbars 2. The carrying tray 1 further has a plurality of upper position-limiting blocks 16 protruding from the plurality of frame walls 12, the plurality of upper position-limiting blocks 16 are respectively correspondingly positioned above the plurality of busbars 2 to limit positions of the plurality of busbars 2. Two of the plurality of busbars 2 are electrode output pieces 2′, each of the other busbars 2 has two electrode connecting portions 21 respectively connecting electrodes 52 of the adjacent two batteries 51 and a buffer bulging portion 22 connected between the two electrode connecting portions 21, the plurality of batteries 51 are connected in series via the plurality of busbars 2 and the two electrode output pieces 2′ are respectively connected to the electrodes 52 at both ends of the series-connection. The carrying tray 1 further has a plurality of support ribs 17 respectively correspondingly supports the plurality of buffer bulging portions 22.

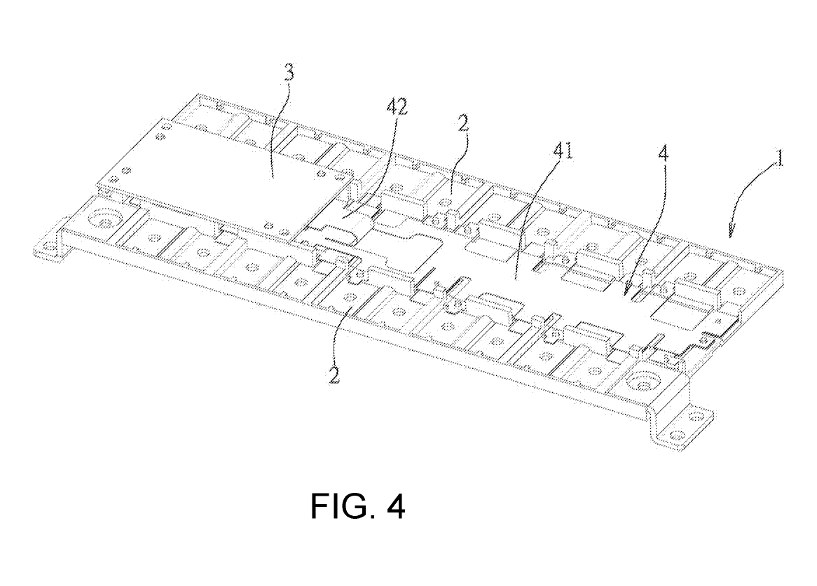

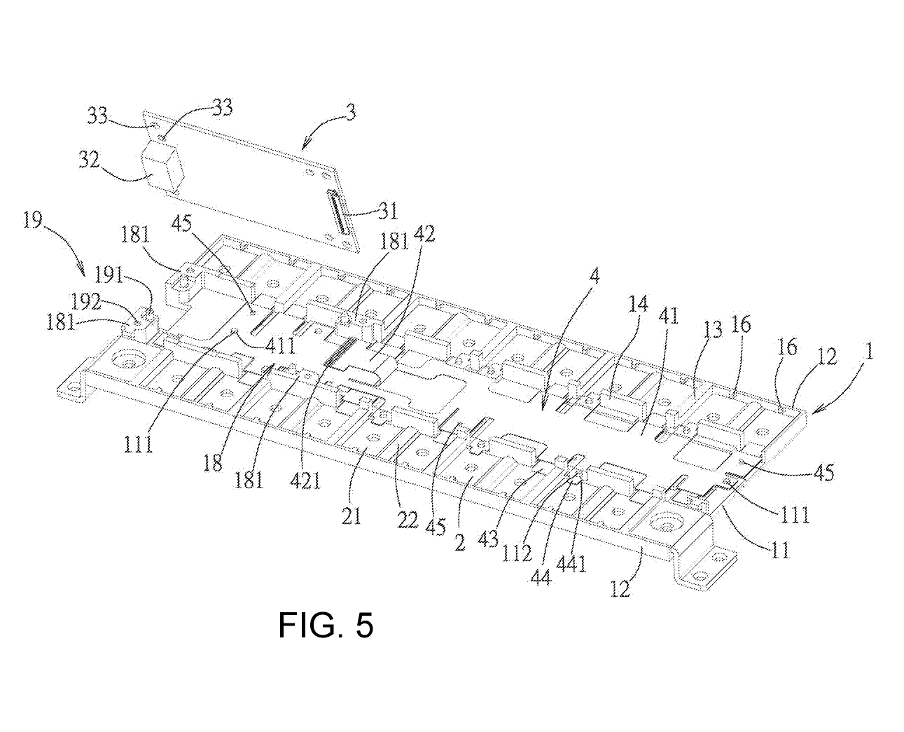

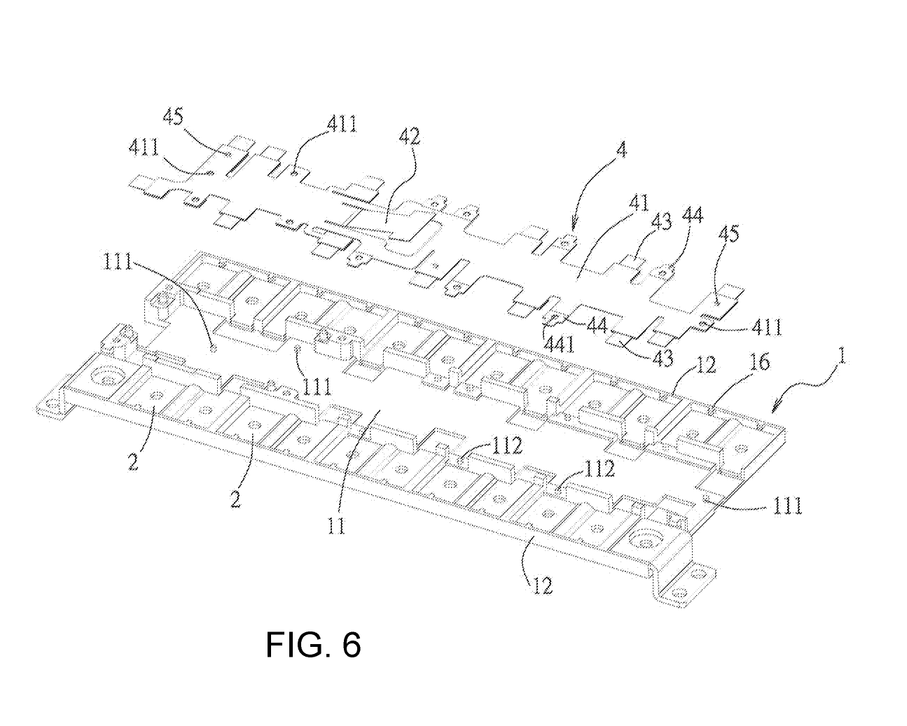

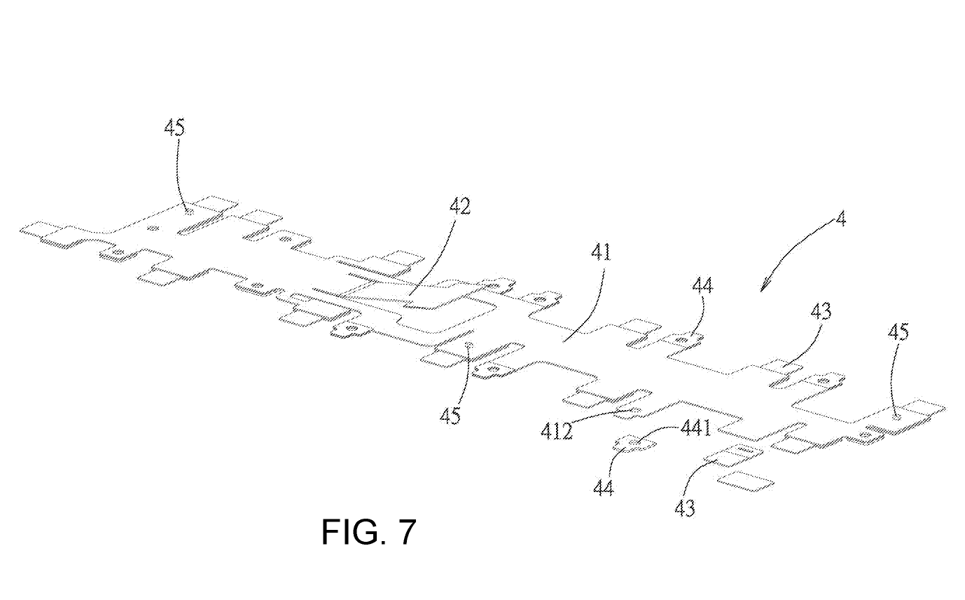

Referring to FIG. 4 to FIG. 7, the BMS 3 is mounted on the carrying tray 1, and comprises a flexible circuit board connector 31 and a main circuit connector 32. The main circuit connector 32 is adapted to connect a main circuit system of a device (not shown) on which the battery pack 5 is mounted. The carrying tray 1 has a mounting position 18 where the BMS 3 is provided so as to allow the BMS 3 to be positioned above the flexible circuit board 4. The carrying tray 1 further has a plurality of first mounting structures 19 provided on a circumferential side of the mounting position 18, and the BMS 3 has a plurality of second mounting structures 33 respectively corresponding to the plurality of the first mounting structures 19 to fix the BMS 3 on the mounting position 18. In the embodiment, the mounting position 18 is defined by four protruding blocks 181 protruding from the base wall 11, positions of the plurality of protruding blocks 181 respectively correspond to four corners of the BMS 3. The plurality of first mounting structures 19 are respectively provided on the protruding blocks 181. The plurality of first mounting structures 19 are positioning posts 191 and locking holes 192, and each protruding block 181 is provided with a positioning post 191 and a locking hole 192. The plurality of second mounting structures 33 are through holes, and the through hole 33 corresponding to the positioning post 191 in position is used to allow the positioning post 191 to pass through, and after the positioning post 191 passes through the through hole 33, the positioning post 191 can be hot melted to fix the BMS 3, and the through hole 33 corresponding to the locking hole 192 in position may allow a fastener, such as a screw (not shown), to pass through to be screwed to the locking hole 192 and fix the BMS 3. In the embodiment, the plurality of first mounting structures 19 are positioning posts 191 and locking holes 192 to strengthen fixation of the BMS 3, but in a variant embodiment, the plurality of first mounting structures 19 can be either positioning posts 191 alone or locking holes 192 alone, which can also have the fixation effect.

The flexible circuit board 4 is mounted on the carrying tray 1 and mechanically and electrically connected to the plurality of busbars 2, and comprises a flexible mating portion 42, and a distal end of the flexible mating portion 42 is mated to the flexible circuit board connector 31 to electrical connect with the flexible circuit board connector 31. In the embodiment, the flexible circuit board 4 further comprises a body portion 41, the flexible mating portion 42 is formed by cutting the body portion 41, three sides of the flexible mating portion 42 are disconnected with the body portion 41 so that the flexible mating portion 42 is formed as an elongated shape and makes one end of the flexible mating portion 42 connected with the body portion 41, and the other end of the flexible mating portion 42 has an exposed conductive wire 421 to mate with the flexible circuit board connector 31. And, the flexible mating portion 42 is bent reversely and then mated with the flexible circuit board connector 31.

In the embodiment, the body portion 41 has a plurality of mounting holes 411, the carrying tray 1 has a plurality of mounting posts 111 respectively passing through the plurality of mounting holes 411, the plurality of mounting posts 111 protrude from the base wall 11 to position the body portion 41 and the carrying tray 1 relative to each other. And the plurality of mounting posts 111 can be further hot melted to fix the body portion 41. The flexible circuit board 4 further comprises a plurality of conductive plates 43 which are connected to the body portion 41 and respectively mechanically and electrically connected to the plurality of busbars 2, and a plurality of upper position-limiting plates 44 which are connected to the body portion 41 and respectively protrude above the plurality of busbars 2. The plurality of busbars 2 electrical connect with the body portion 41 via the plurality of conductive plates 43, and then circuit traces of the body portion 41 (not shown) are connected to the conductive wires 421 of the flexible mating portion 42, and the plurality of conductive wires 421 are electrically connected with the flexible circuit board connector 31, so that the plurality of busbars 2 are electrically connected with the BMS 3. In addition, in the embodiment, the flexible circuit board 4 further comprises a plurality of temperature sensors 45 provided on the body portion 41, the plurality of temperature sensors 45 are also electrically connected with the BMS 3 via circuit traces of the body portion 41 and the flexible mating portion 42. Each upper position-limiting plate 44 has a fixing hole 441, the carrying tray 1 has a plurality of fixing posts 112 respectively passing through the plurality of fixing holes 441, and the body portion 41 further has a plurality of through holes 412 which respectively correspond to the plurality of fixing holes 441 in position to respectively allow the plurality of fixing posts 112 to pass through. The plurality of fixing posts 112 may be further hot melted to fix the plurality of upper position-limiting plates 44. The plurality of upper position-limiting plates 44 and the plurality of upper position-limiting blocks 16 cooperatively correspondingly limit the positions of the plurality of busbars 2.

In conclusion, the BMS 3 is directly mounted on and coupled to the carrying tray 1 and is electrically connected with the busbars 2 via the flexible circuit board 4, so that they are integrated to an integrated module that facilitates subsequent assembly and use. And the BMS 3 only needs to be provided with one flexible circuit board connector 31 to directly connect with the flexible circuit board 4, which can reduce the number of components and save cost. Furthermore, the flexible mating portion 42 connected to the BMS 3 is formed by cutting the body portion 41 constituting the flexible circuit board 4, which can effectively utilize the space, and is easy to cooperate to the position where the BMS 3 is coupled to the carrying tray 1, so that the position where the BMS 3 is provided has flexibility of change.

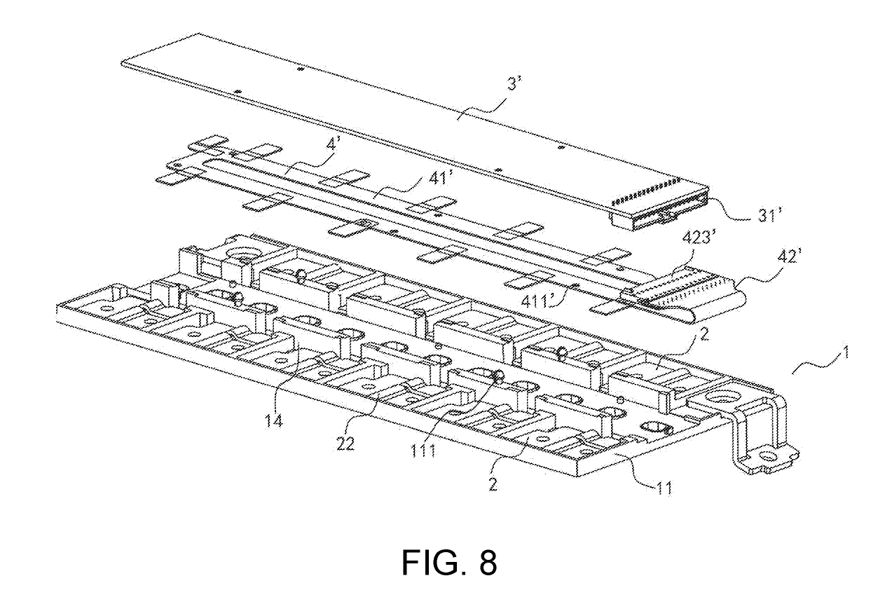

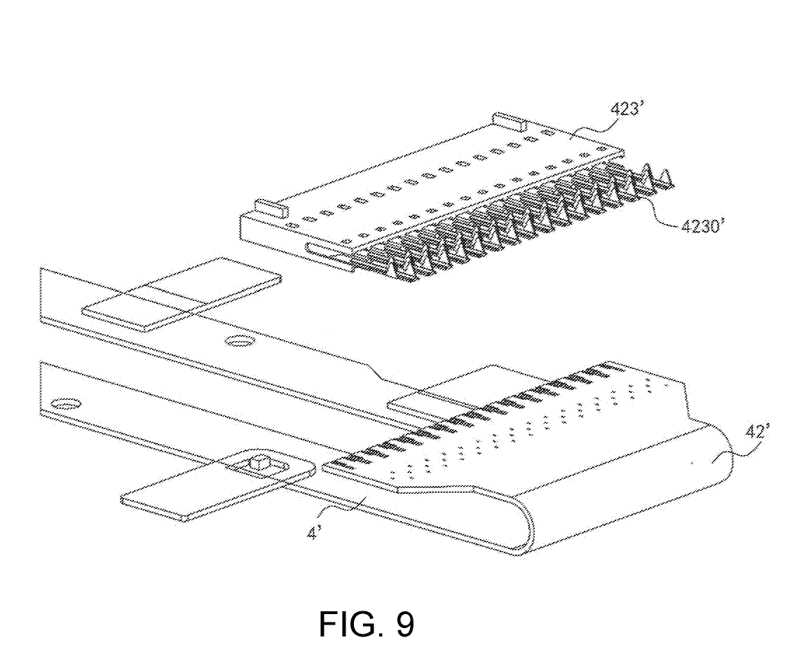

A second embodiment of the present disclosure will now be described with reference to FIG. 8 and FIG. 9, and FIG. 8 is a perspective view of a second embodiment of the battery connection module of the present disclosure; FIG. 9 is a perspective view showing details of the flexible insertion portion of the embodiment. For the sake of brevity, only parts different from the above-described embodiment will be described herein, and the description of the remaining identical parts can be referred to the above.

As shown in FIG. 8, in the embodiment, the flexible mating portion 42′ of the flexible circuit board 4′ is provided on one end portion of the flexible circuit board 4′, that is, the flexible mating portion 42′ extends outwardly from one end edge (a right end edge shown in the figures) of the body portion 41′ of the flexible circuit board 4′, and bends 180 degrees reversely to connect to a connector 423′, referring to FIG. 9, the connector 423′ is provided with terminals 4230′, the terminal 4230′ will pierce the flexible circuit board 4′ and electrical connect with conductive wires of the flexible circuit board 4′. The connector 423′ will correspondingly mate with the connector 31′ of the BMS 3′, so as to realize the electrical connection between the plurality of busbars 2 and the BMS 3′ via the flexible circuit board 4′.

In the embodiment, in order to realize that the connector 423′ correspondingly mates with the connector 31′ on the BMS 3′, a length of the BMS 3′ is extended to allow the connector 31′ of the BMS 3′ to correspondingly mate with the connector 423′ of the flexible mating portion 42′. Of course, the length of the BMS 3′ may also remain unchanged, and the flexible mating portion 42′ is bent reversely and then continues to extend until the flexible mating portion 42′ can correspondingly mate with the connector 31′ of the BMS 3′.

In addition, for example, the flexible mating portion 42′ may also extend outwardly from the left side of the flexible circuit board 4′ as shown in the figures and reversely bend 180 degrees to connect to the connector 423′, correspondingly, the connector 31′ of the BMS 3′ is also correspondingly provided on an end edge of a left side of the BMS 3′ as shown in the figures, so as to correspondingly mate with the connector 423′ of the flexible mating portion 42′. In this case, the length of the BMS 3′ is also no longer required to be extended.

Based on the above embodiment, the BMS 3′ can be electrically connected with the busbars 2 via the flexible circuit board 4′, so that they are integrated to the integrated module that facilitates subsequent assembly and use. And, the BMS 3′ only needs to be provided with one connector 31′ to directly connect with the flexible circuit board 4′, which can reduce the number of components and save cost. And one end edge of the flexible circuit board 4′ directly extends out of the flexible mating portion 42′, so that its structure and production process are more simplified.

However, the above description is only for the embodiments of the present disclosure, and the scope of the present disclosure is not limited thereto, and all the simple equivalent changes and modifications according to the scope of the patent application and the patent specification of the present disclosure are still within the scope of the patent of the present disclosure.

What is claimed is:

1. A battery connection module, adapted to connect a battery pack, the battery connection module comprising:
a carrying tray;
a plurality of busbars mounted on the carrying tray and adapted to electrically connect a plurality of batteries of the battery pack;
a battery management system (BMS) mounted on the carrying tray, positioned above the flexible circuit board and comprising a connector; and
a flexible circuit board mounted on the carrying tray, mechanically and electrically connected to the plurality of busbars and comprising a body portion and an extending flexible mating portion, a distal end of the flexible mating portion being connected to the connector of the BMS.

2. The battery connection module of claim 1, wherein the flexible mating portion is formed by cutting the body portion.

3. The battery connection module of claim 2, wherein three sides of the flexible mating portion are disconnected with the body portion, so that the flexible mating portion is form as an elongated shape and makes one end of the flexible mating portion connected with the body portion.

4. The battery connection module of claim 1, wherein the flexible mating portion extends outwardly from one end edge of the body portion of the flexible circuit board.

5. The battery connection module of claim 1, wherein the connector is a flexible circuit board connector, the flexible mating portion has exposed conductive wires to mate with the flexible circuit board connector.

6. The battery connection module of claim 1, wherein the flexible mating portion is mounted to another connector to correspondingly mate with the connector of the BMS.

7. The battery connection module of claim 1, wherein the carrying tray has a mounting position where the BMS is provided so as to allow the BMS to be positioned above the flexible circuit board.

8. The battery connection module of claim 7, wherein the carrying tray further has a plurality of first mounting structures provided on a circumferential side of the mounting position, and the BMS has a plurality of second mounting structures respectively corresponding to the plurality of first mounting structures to fix the BMS on the mounting position.

9. The battery connection module of claim 8, wherein the plurality of first mounting structures are positioning posts and/or locking holes, the plurality of second mounting structures are through holes corresponding to the positioning posts and/or the locking holes.

10. The battery connection module of claim 8, wherein the mounting position is defined by four protruding blocks, the positions of the protruding blocks respectively correspond to four corners of the BMS, the plurality of first mounting structures are respectively provided on the protruding blocks.

11. The battery connection module of claim 10, wherein the plurality of first mounting structures are positioning posts and/or locking holes, the plurality of second mounting structures are through holes corresponding to the positioning posts and/or the locking holes.

12. The battery connection module of claim 1, wherein the flexible circuit board further comprises a plurality of conductive plates which are connected to the body portion and respectively mechanically and electrically connected to the plurality of busbars.

13. The battery connection module of claim 1, wherein the flexible circuit board further comprises a plurality of upper position-limiting plates which are connected to the body portion and respectively protrudes above the plurality of busbars.

14. The battery connection module of claim 13, wherein each upper position-limiting plate has a fixing hole, the carrying tray has a plurality of fixing posts respectively passing through the plurality of fixing holes.

15. The battery connection module of claim 1, wherein the flexible circuit board has a plurality of mounting holes, the carrying tray has a plurality of mounting posts respectively passing through the plurality of mounting holes.
